(19) United States
(12) Patent Application Publication
(10) Pub. No.: US 2016/0080119 A1
(43) Pub. Date: Mar. 17, 2016

(54) SELF-TEST GSM/EDGE POWER MEASUREMENT

(71) Applicant: QUALCOMM Incorporated, San Diego, CA (US)

(72) Inventors: Rema Vaidyanathan, San Diego, CA (US); Prasad Srinivasa Siva Gudem, San Diego, CA (US); Vijay Chellappa, San Diego, CA (US); Chalin Chac Lee, San Diego, CA (US); Li Gao, San Diego, CA (US); David Coronel, San Diego, CA (US)

(21) Appl. No.: 14/484,523

(22) Filed: Sep. 12, 2014

(51) Int. Cl. H04L 1/20; H04L 1/24; H03L 7/06; H04B 1/10; H04W 72/04; H04L 7/033; H04B 3/46

(52) U.S. Cl. CPC H04L 1/206; H04L 7/0331; H04L 1/24; H04B 3/46; H04B 1/10; H04W 72/04; H03L 7/06

(57) ABSTRACT

A method and apparatus for self-testing a GSM/EDGE communications device. An embodiment provides a method of measuring transmit power. A receive phase locked loop (PLL) is inserted into a feedback receiver local oscillator mixer. The receive PLL is then tuned to a local oscillator frequency. Once the tuning is complete, an I and a Q signal are captured using a channel of the feedback receiver. After capture, a I2+Q2 sum is computed, measuring the transmit power. The feedback receiver automatic gain control (AGC) may be used to determine transmit power in place of I2+Q2. The apparatus includes: a modem assembly, a power control assembly, a power amplifier, a duplexer, a coupler and a switch. The power control assembly further includes a first PLL and first and second mixers. The second mixer is connected to a feedback low noise amplifier and receives input from a feedback receiver PLL.

### FIELD

The present disclosure relates generally to wireless communication systems, and more particularly to a method for self-test GSM/EDGE power management.

### BACKGROUND

Wireless communication devices have become smaller and more powerful as well as more capable. Increasingly users rely on wireless communication devices for mobile phone use as well as email and Internet access. At the same time, devices have become smaller in size. Devices such as cellular telephones, personal digital assistants (PDAs), laptop computers, and other similar devices provide reliable service with expanded coverage areas. Such devices may be referred to as mobile stations, stations, access terminals, user terminals, subscriber units, user equipments, and similar terms.

A wireless communication system may support communication for multiple wireless communication devices at the same time. In use, a wireless communication device may communicate with one or more base stations by transmissions on the uplink and downlink. Base stations may be referred to as access points, Node Bs, or other similar terms. The uplink or reverse link refers to the communication link from the wireless communication device to the base station, while the downlink or forward link refers to the communication from the base station to the wireless communication devices.

Wireless communication systems may be multiple access systems capable of supporting communication with multiple users by sharing the available system resources, such as bandwidth and transmit power. Examples of such multiple access systems include code division multiple access (CDMA) systems, time division multiple access (TDMA) systems, frequency division multiple access (FDMA) systems, wideband code division multiple access (WCDMA) systems, global system for mobile (GSM) communication systems, enhanced data rates for GSM evolution (EDGE) systems, and orthogonal frequency division multiple access (OFDMA) systems.

Global System for Mobile (GSM) communications is a standard developed by the European Telecommunications Standards Institute (ETSI) to describe protocols for second generation (2G) digital cellular networks used by mobile phones. GSM networks operate in a number of different carrier frequency ranges separated into GSM frequency ranges. The frequency selected by an operator is divided into timeslots for individual phones. This allows eight full-rate or sixteen half-rate speech channels per frequency. These eight radio timeslots, or burst periods, are grouped into a time division multiple access (TDMA) frame. Half-rate channels use alternate frames in the same timeslot.

Enhanced Data Rates for GSM Evolution (EDGE) allows improved data transmission rates as a backward compatible extension of GSM. EDGE delivers higher bit rates per radio channel, and may provide a threefold increase in capacity. EDGE can be used for any packet switch application, such as an internet connection.

EDGE uses Gaussian minimum shift keying (GMSK) and uses higher order phase shift keying (8 PSK) for the upper five of its nine modulation and coding schemes. EDGE produces a 3-bit word for every change in carrier phase. EDGE uses incremental redundancy, which, instead of retransmitting disturbed packets, send more redundancy to be combined in the receiver, to increase the probability of correct decoding.

The channel coding process in EDGE consists of two steps: first, a cyclic code is used to add parity bits, which are also referred to as the Block Check Sequence, followed by coding with a possibly punctured convolutional code. A convolutional code rate of ⅓ is used.

As the use of mobile devices has increased the need to deliver devices to market fully tested. In some modem solutions, technology has been developed to enable self-test of the transmitter for 3G and 4G technologies, however, self-test for the older 2G technology has not been developed. In addition, in the manufacturing process, where power calibration is required, measurement speed may be a significant factor. To fully calibrate and characterize a GSM/EDGE transceiver may require hundreds of measurements, taking significant time for each transceiver. There is a need in the art for a method and apparatus for self-testing 2G devices.

### SUMMARY

Embodiments contained in the disclosure provide a method of self-testing a GSM/EDGE communications device. An embodiment provides a method of measuring transmit power. The method begins when a receive phase locked loop (PLL) is inserted into a feedback receiver local oscillator mixer. The receive PLL is then tuned to a local oscillator frequency. Once the tuning is complete, an I and a Q signal are captured using a channel of the feedback receiver. After capture, a I2+Q2 sum is computed, thus measuring the transmit power. The feedback receiver automatic gain control (AGC (may be used to determine transmit power in place of I2+Q2.

A further embodiment provides an apparatus for measuring output RF spectrum modulation. The method begins when a receive PLL is inserted into a feedback receiver local oscillator mixer and then tuned to a right transmit channel. Additional embodiments provide a method for measuring output RF spectrum modulation by determining a difference between the feedback receiver noise floor and a transmit modulation measurement. Yet further embodiments provide for measuring output RF spectrum switching across a full transmit slot, as well as measuring output RF spectrum switching by capturing transmit slot turn on and off boundaries.

A still further embodiment provides an apparatus for self-testing of a communications device. The apparatus includes: a modem assembly, a power control assembly, a power amplifier, a duplexer, a coupler and a switch. The power control assembly further includes a first PLL and first and second mixers. The second mixer is connected to a feedback low noise amplifier and receives input from a feedback receiver PLL.

### BRIEF DESCRIPTION OF THE DRAWINGS

FIG. 1 illustrates a wireless multiple-access communication system, in accordance with certain embodiments of the disclosure.

FIG. 2 is a block diagram of a wireless communication system in accordance with embodiments of the disclosure.

FIG. 3 is a block diagram of an apparatus for GSM/EDGE transmission and feedback receive capture in accordance with embodiments of the disclosure.

FIG. 4 illustrates the theory of transmitted RF carrier power versus time, in accordance with certain embodiments of the disclosure.

FIG. 5 illustrates the transmit slot power amplifier profile, in accordance with certain embodiments of the disclosure.

FIG. 6 is a flow diagram of a method of measuring transmit power, in accordance with certain embodiments of the disclosure.

FIG. 7 is a flow diagram of a method for measuring output RF spectrum modulation in accordance with certain embodiments of the disclosure.

FIG. 8 is a flow diagram of a method for measuring an output of RF switching for a full transmit slot, in accordance with certain embodiments of the disclosure.

FIG. 9 is a flow diagram of a method for measuring output RF switching by capturing transmit slot boundaries, in accordance with certain embodiments of the disclosure.

FIG. 10 is a flow diagram of a method of measuring EDGE EVM in accordance with certain embodiments of the disclosure.

### DETAILED DESCRIPTION

The detailed description set forth below in connection with the appended drawings is intended as a description of exemplary embodiments of the present invention and is not intended to represent the only embodiments in which the present invention can be practiced. The term “exemplary” used throughout this description means “serving as an example, instance, or illustration,” and should not necessarily be construed as preferred or advantageous over other exemplary embodiments. The detailed description includes specific details for the purpose of providing a thorough understanding of the exemplary embodiments of the invention. It will be apparent to those skilled in the art that the exemplary embodiments of the invention may be practiced without these specific details. In some instances, well-known structures and devices are shown in block diagram form in order to avoid obscuring the novelty of the exemplary embodiments presented herein.

As used in this application, the terms “component,” “module,” “system,” and the like are intended to refer to a computer-related entity, either hardware, firmware, a combination of hardware and software, software, or software in execution. For example, a component may be, but is not limited to being, a process running on a processor, an integrated circuit, a processor, an object, an executable, a thread of execution, a program, and/or a computer. By way of illustration, both an application running on a computing device and the computing device can be a component. One or more components can reside within a process and/or thread of execution and a component may be localized on one computer and/or distributed between two or more computers. In addition, these components can execute from various computer readable media having various data structures stored thereon. The components may communicate by way of local and/or remote processes such as in accordance with a signal having one or more data packets (e.g., data from one component interacting with another component in a local system, distributed system, and/or across a network, such as the Internet, with other systems by way of the signal).

Furthermore, various aspects are described herein in connection with an access terminal and/or an access point. An access terminal may refer to a device providing voice and/or data connectivity to a user. An access wireless terminal may be connected to a computing device such as a laptop computer or desktop computer, or it may be a self-contained device such as a cellular telephone. An access terminal can also be called a system, a subscriber unit, a subscriber station, mobile station, mobile, remote station, remote terminal, a wireless access point, wireless terminal, user terminal, user agent, user device, or user equipment. A wireless terminal may be a subscriber station, wireless device, cellular telephone, PCS telephone, cordless telephone, a Session Initiation Protocol (SIP) phone, a wireless local loop (WLL) station, a personal digital assistant (PDA), a handheld device having wireless connection capability, or other processing device connected to a wireless modem. An access point, otherwise referred to as a base station or base station controller (BSC), may refer to a device in an access network that communicates over the air-interface, through one or more sectors, with wireless terminals. The access point may act as a router between the wireless terminal and the rest of the access network, which may include an Internet Protocol (IP) network, by converting received air-interface frames to IP packets. The access point also coordinates management of attributes for the air interface.

Moreover, various aspects or features described herein may be implemented as a method, apparatus, or article of manufacture using standard programming and/or engineering techniques. The term “article of manufacture” as used herein is intended to encompass a computer program accessible from any computer-readable device, carrier, or media. For example, computer readable media can include but are not limited to magnetic storage devices (e.g., hard disk, floppy disk, magnetic strips . . . ), optical disks (e.g., compact disk (CD), digital versatile disk (DVD) . . . ), smart cards, and flash memory devices (e.g., card, stick, key drive . . . ), and integrated circuits such as read-only memories, programmable read-only memories, and electrically erasable programmable read-only memories.

Various aspects will be presented in terms of systems that may include a number of devices, components, modules, and the like. It is to be understood and appreciated that the various systems may include additional devices, components, modules, etc. and/or may not include all of the devices, components, modules etc. discussed in connection with the figures. A combination of these approaches may also be used.

Other aspects, as well as features and advantages of various aspects, of the present invention will become apparent to those of skill in the art through consideration of the ensuring description, the accompanying drawings and the appended claims.

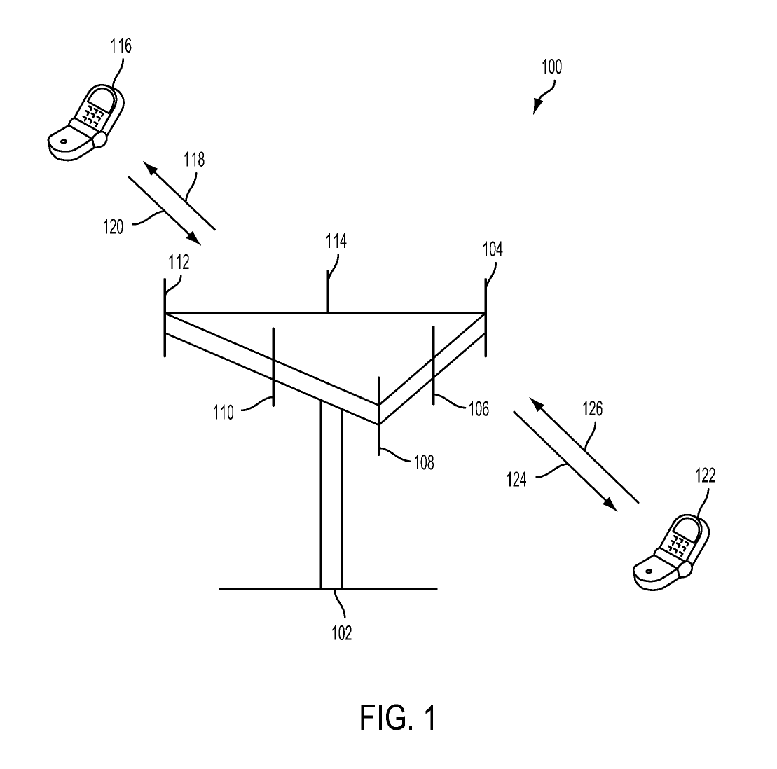

FIG. 1 illustrates a multiple access wireless communication system 100 according to one aspect. An access point 102 (AP) includes multiple antenna groups, one including 104 and 106, another including 108 and 110, and an additional one including 112 and 114. In FIG. 1, only two antennas are shown for each antenna group, however, more or fewer antennas may be utilized for each antenna group. Access terminal 116 (AT) is in communication with antennas 112 and 114, where antennas 112 and 114 transmit information to access terminal 116 over downlink or forward link 118 and receive information from access terminal 116 over uplink or reverse link 120. Access terminal 122 is in communication with antennas 106 and 108, where antennas 106 and 108 transmit information to access terminal 122 over downlink or forward link 124, and receive information from access terminal 122 over uplink or reverse link 126. In a frequency division duplex (FDD) system, communication link 118, 120, 124, and 126 may use a different frequency for communication. For example, downlink or forward link 118 may use a different frequency than that used by uplink or reverse link 120.

Each group of antennas and/or the area in which they are designed to communicate is often referred to as a sector of the access point. In an aspect, antenna groups are each designed to communicate to access terminals in a sector of the areas covered by access point 102.

In communication over downlinks or forward links 118 and 124, the transmitting antennas of an access point utilize beamforming in order to improve the signal-to-noise ration (SNR) of downlinks or forward links for the different access terminals 116 and 122. Also, an access point using beamforming to transmit to access terminals scattered randomly through its coverage causes less interference to access terminals in neighboring cells than an access point transmitting through a single antenna to all its access terminals.

An access point may be a fixed station used for communicating with the terminals and may also be referred to as a Node B, an evolved Node B (eNB), or some other terminology. An access terminal may also be called a mobile station, user equipment (UE), a wireless communication device, terminal or some other terminology. For certain aspects, either the AP 102, or the access terminals 116, 122 may utilize the techniques described below to improve performance of the system.

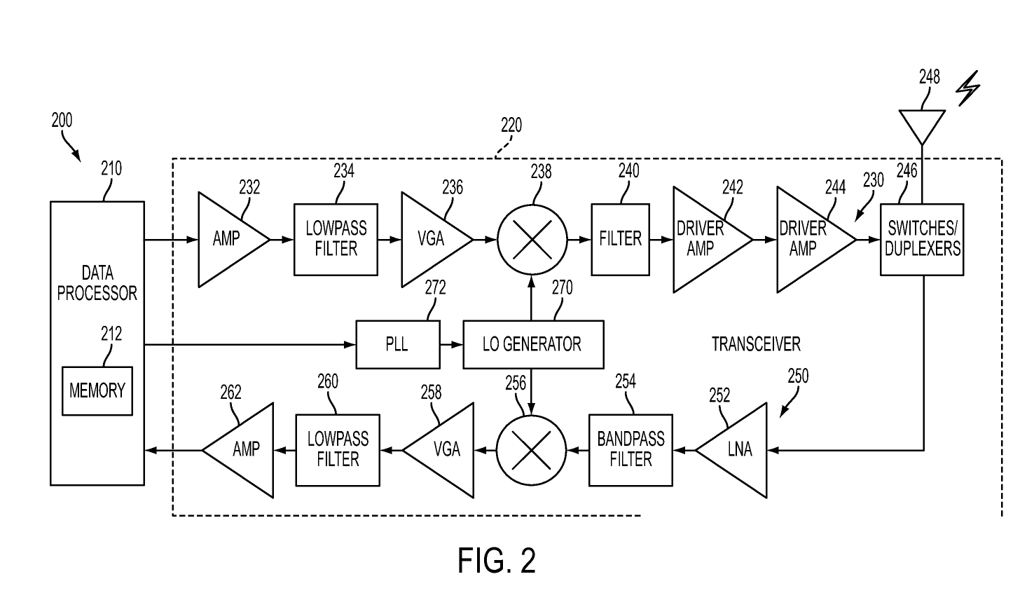

FIG. 2 shows a block diagram of an exemplary design of a wireless communication device 200. In this exemplary design, wireless device 200 includes a data processor 210 and a transceiver 220. Transceiver 220 includes a transmitter 230 and a receiver 250 that support bi-directional wireless communication. In general, wireless device 200 may include any number of transmitters and any number of receivers for any number of communication systems and any number of frequency bands.

In the transmit path, data processor 210 processes data to be transmitted and provides an analog output signal to transmitter 230. Within transmitter 230, the analog output signal is amplified by an amplifier (Amp) 232, filtered by a lowpass filter 234 to remove images caused by digital-to-analog conversion, amplified by a VGA 236, and upconverted from baseband to RF by a mixer 238. The upconverted signal is filtered by a filter 240, further amplified by a driver amplifier, 242 and a power amplifier 244, routed through switches/duplexers 246, and transmitted via an antenna 249.

In the receive path, antenna 248 receives signals from base stations and/or other transmitter stations and provides a received signal, which is routed through switches/duplexers 246 and provided to receiver 250. Within receiver 250, the received signal is amplified by an LNA 252, filtered by a bandpass filter 254, and downconverted from RF to baseband by a mixer 256. The downconverted signal is amplified by a VGA 258, filtered by a lowpass filter 260, and amplified by an amplifier 262 to obtain an analog input signal, which is provided to data processor 210.

FIG. 2 shows transmitter 230 and receiver 250 implementing a direct-conversion architecture, which frequency converts a signal between RF and baseband in one stage. Transmitter 230 and/or receiver 250 may also implement a super-heterodyne architecture, which frequency converts a signal between RF and baseband in multiple stages. A local oscillator (LO) generator 270 generates and provides transmit and receive LO signals to mixers 238 and 256, respectively. A phase locked loop (PLL) 272 receives control information from data processor 210 and provides control signals to LO generator 270 to generate the transmit and receive LO signals at the proper frequencies.

FIG. 2 shows an exemplary transceiver design. In general, the conditioning of the signals in transmitter 230 and receiver 250 may be performed by one or more stages of amplifier, filter, mixer, etc. These circuits may be arranged differently from the configuration shown in FIG. 2. Some circuits in FIG. 2 may also be omitted. All or a portion of transceiver 220 may be implemented on one or more analog integrated circuits (ICs), RF ICs (RFICs), mixed-signal ICs, etc. For example, amplifier 232 through power amplifier 244 in transmitter 230 may also be implemented on an RFIC. Driver amplifier 242 and power amplifier 244 may also be implemented on another IC external to the RFIC.

Data processor 210 may perform various functions for wireless device 200, e.g., processing for transmitter and received data. Memory 212 may store program codes and data for data processor 210. Data processor 210 may be implemented on one or more application specific integrated circuits (ASICs) and/or other ICs.

The modem in a mobile device provides transmission and reception of signals. Increasing use of mobile devices has led to the development of self-testing methods and apparatus for 3G and 4G devices, but not 2G devices using GSM and EDGE networks. The parameters that need to be tested are: 1) transmit power, 2) root-mean-square (RMS) and peak phase error, and 3) output RF spectrum (ORFS) modulation/switching. In many modems used by mobile devices today such testing is not possible because of architecture limitations with the feedback receiver local oscillator (FBRxLO). The FBRxLO is sourced by the transmit phase locked loop (TxPLL) and because GSM is phase modulated on the transmit LO it is not possible to retrieve the phase information at the FBRx and measure the needed parameters.

Phase error (GMSK) and error vector magnitude (EVM) are fundamental parameters used in GSM to characterize modulation accuracy. These measurements may reveal significant information about transmitter performance. Poor phase error or EVM may indicate a problem with the I/Q baseband generator, filters, modulator, or amplifier in the transmitter circuitry. Poor phase error or EVM reduces the ability of a receiver to correctly demodulate desired received signals, especially in marginal signal conditions.

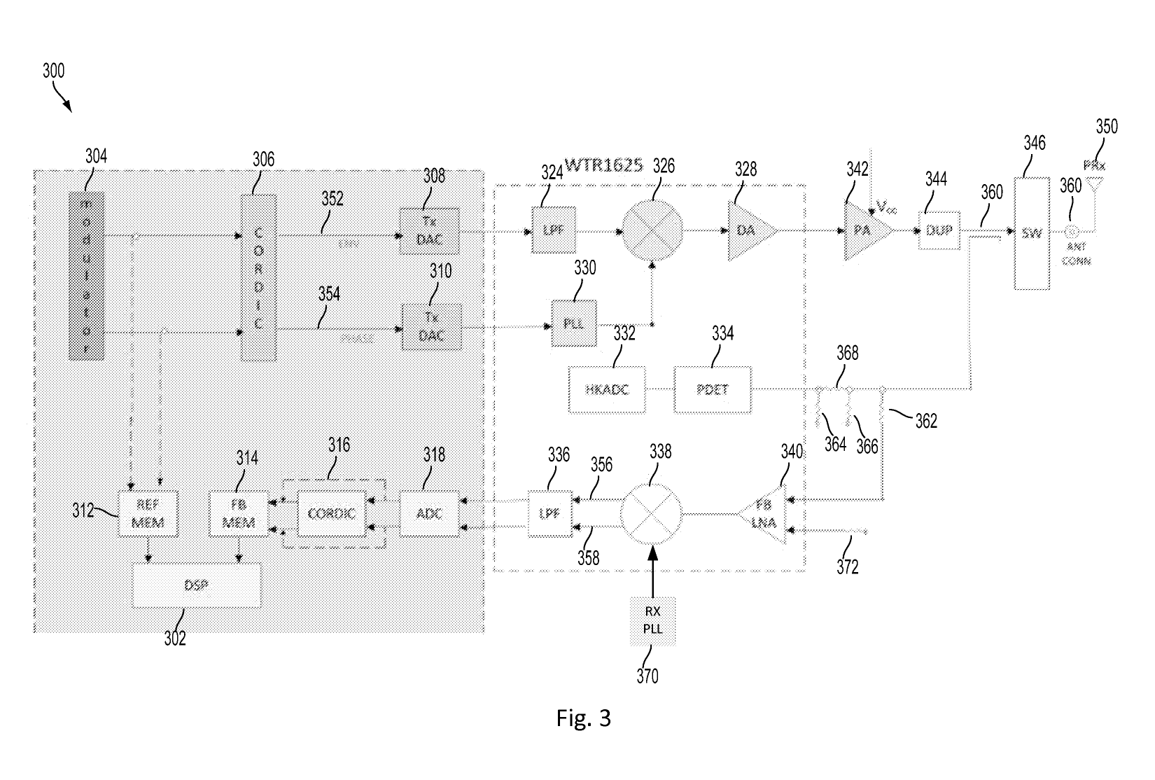

FIG. 3 depicts an embodiment of the problem of GSM and EDGE self-test on 2G modems. The assembly 300, includes modem 302 section. Modem section 302 contains modulator 304, which is connected to a rectangular to polar converter, known as a CORDIC, 306. Modulator 304 provides two inputs to CORDIC A 306. CORDIC A 306 outputs two signals, an envelope signal 352 and a phase signal 354. Envelope signal 352 is input to transmit digital-to-analog converter (TxDAC) 308. In similar fashion, phase signal 354 is input to a second TxDAC 310. Reference memory 312 samples both signals 352 and 354 output from modulator 304 prior to those signals passing into CORDIC A 306. Reference memory 312 provides input to digital signal processor (DSP) 320.

A power control chip 322 filters power and also provides filtering for the two signals exiting TxDACs 308 and 310. The envelope signal 352 exiting from TxDAC 308 is input to a first low-pass filter (LPF) A, 324. The phase signal 354 exiting from TxDAC 310 is input to a phase locked loop (PLL) 330. Both signals are input to a first mixer A, 326. In mixer A 326, a baseband frequency is mixed with a local oscillator (LO) frequency.

The output mixer A 326 is input to digital amplifier (DA) 328 and the output of digital amplifier 328 is input to power amplifier (PA) 342, which also receives a voltage input. The resulting output is passed to a duplexer (DUP) 344. The output from DUP 344 is passed through coupler 360. Coupler 360 is also coupled to switch 346.

Coupler 360 allows examination of the transmit signal at the point where the coupler is inserted. The coupler 350 samples the amplified forward RF signal and also reduces the amplification of the signal. The RF signal is further reduced by attenuator 362. Coupler 360 is also linked to attenuators 362 and 366 as well as source resistors 364 and 368. Source resistors may be 50 ohm resistors, however, the value of these source resistors may be adjusted depending on system and application, and the invention is not limited to the stated values. The RF signal is then fed into feedback low noise amplifier (FB LNA) 340. FB LNA 340 is also connected to load resistor 372. Typically, a load resistor my provide a 50 ohm load.

First mixer A 326 is also connected to second mixer B 338. Second mixer B 338 may be an I and Q mixer. Second mixer B receives the RF signal from along with a local oscillator frequency from PLL 330. The output from first mixer A 326 is input to a digital amplifier 328. Phase signal 354 exits TxDAC 310 and is input to PLL 330. PLL 330 acts as a local oscillator (LO) to step up or down a signal frequency. The output from PLL 330 is connected to the signal passing between mixer A 326 and mixer B 338.

Mixer B 338 provides two inputs, a first signal 356 which is output from mixer B 338 and a second signal 358, which is output from mixer B 338. Mixer B 338 also receives input from receive PLL 370. Receive PLL 370 provides a feedback receiver local oscillator (FBrxLO) having better phase noise performance than PLL 330. This allows measurement of ORFS performance in a GSM/EDGE system. Signals 356 and 358 may be I and Q signals. Both signals 356 and 358 are input to a second low pass filter (LPF) B 336. LPF B 336 extracts the baseband I and Q signals. These signals 356 and 358 are then passed to analog to digital converter (ADC) 318, where the signals are converted to digital signals. ADC 318 passes both the first and second digital signals to CORDIC B 316. The output from CORDIC B is stored in feedback (FB) memory 314. Optionally, CORDIC b may be bypassed, as indicated by the dashed line. FB memory 314 also provides input to DSP 320.

In operation, DSP 320 receives signals from reference memory 312 and feedback memory 314. DSP 320 then performs a Fast Fourier Transform (FFT). The resulting FFT is plotted for both the reference and feedback signals and the difference between the reference and feedback signals is measured. This measured value is the output RF spectrum at the switch 346 (ORFS_SW).

The measured signal from coupler 360, after passing through source resistors 368 and 364, as well as attenuator 366 is then sent to power detector (PDET) 334. PDET 334 detects the RF signal and converts it to a DC value. This DC value is then passed to the housekeeping analog to digital converter (HKDAC). This digital value is used by power control chip 322 to control the power output.

Switch 346 coupled to antenna connector 348, and thence to antenna 350, for transmission and reception of signals. Antenna 350 may be primary receive (PRx) antenna, or may be any of a number of diversity antennas, depending on need and particular mobile device.

The method operates by sourcing the FBRxLO using a PLL that has better phase noise performance than the TxLO the ORFS performance may be measured. The RxPLL should be able to tune to the TxLO frequency. Once the Tx and Rx PLLs are tuned to the same transmit frequency, an IQ capture is performed using the feedback receiver. To measure the transmit power, I2+Q2 may be computed or the automatic gain control (AGC) of the feedback receiver may be used.

One important test for a GSM/EDGE transceiver is measurement of transmitted RF carrier power versus time. This measurement assesses the envelope of carrier power in the time domain against a prescribed mask. In GSM/EDGE systems transmitters must ramp power up and down within a TDMA structure to prevent adjacent timeslot interference. If a transmitter turns on too slowly, data at the beginning of the burst might be lost, degrading link quality. If a transmitter turns off too slowly the user of the next timeslot in the TDMA frame experiences interference. This measurement also verifies that the transmitter turns off completely.

If a transmitter fails the “transmitted RF carrier power versus time” test, it may indicate a problem with the mobile device's output amplifier or leveling loop. While helpful, the test does not check to see if transmitter power ramps up too quickly. When transmitter power ramps up too quickly, the energy appears to spread across the spectrum and may cause interference. The “spectrum due to switching” measurement may be used to test for this effect.

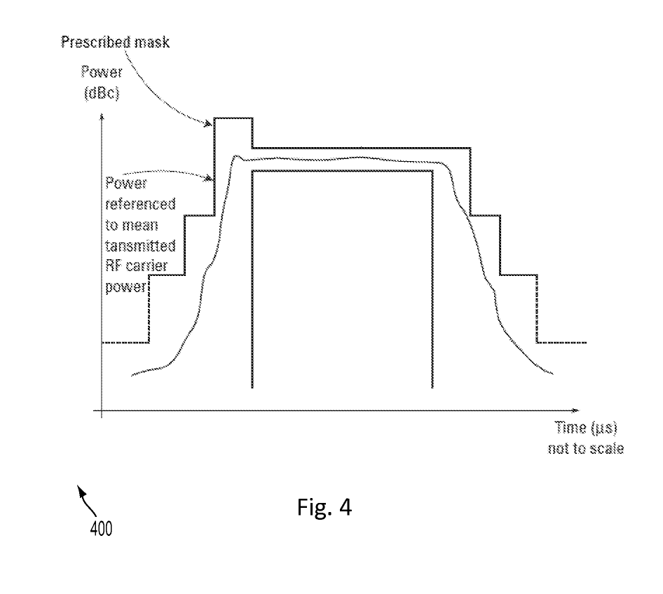

FIG. 4 depicts the theory of transmitted RF carrier power versus time. The measurement of RF carrier power versus time is typically made using an analyzer in zero-span mode. The pass/fail mask is placed over the measured trace and may be referenced two ways. The horizontal axis represents the time axis and the measurement may be referenced from the transition between symbols 13 and 14 of a training sequence. Therefore, it is necessary for the test equipment to demodulate this measurement correctly. The power axis is the vertical axis, and the measurement is referenced against the measurement of mean transmitted RF carrier power. However, the drawback of the method just described is multiple measurements requiring specialized test equipment.

GSM/EDGE testing also requires measuring adjacent channel power. Adjacent channel power is defined by standards organizations such as 3GPP, as two measurements: spectrum due to modulation and wideband noise, and spectrum due to switching.

Spectrum due to modulation and wideband noise and spectrum due to switching may be grouped together and known as “output RF spectrum” (ORFS). The modulation process in a transmitter causes the continuous wave (CW) carrier to spread spectrally. The spectrum due to modulation and wideband noise measurement ensures that the modulation process does not cause excessive spectral spread. If it did, other users operating on different frequencies would experience interference. The measurement of the spectrum due to modulation and wideband noise can be thought of as an adjacent channel power (ACP) measurement, although several adjacent channels are tested.

This measurement, along with the phase error measurement, may reveal numerous faults in the transmit chain, such as faults in the I/Q baseband generator, filters and modulator. The measurement also checks for wideband noise from the transmitter. The specification requires testing of the entire transmit band. If the transmitter produces excessive wideband noise, other users will experience interference.

Previously, the measurement was made using an external analyzer. The analyzer was tuned to a spot frequency and then time-gated across part of the modulated burst. Power is then measured using this mode and then the analyzer is re-tuned to the next frequency, or the offset of interest. This process continues until all the offsets are measured and checked against permissible limits. What results is the spectrum of the signal, however, spectral components that result from the effect of bursting do not appear because the ramps are gated out.

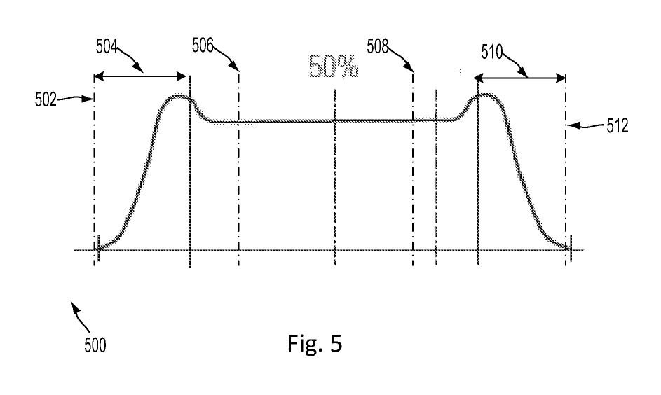

FIG. 5 illustrates the power measurement and shows the 50-90% gating points. 502 shows the signal behavior at power amplifier (PA) power on. 504 indicates the PA ramp up signal. The 20% slot point is depicted at point 506 and the 80% slot point is found at 508. PA ramp-down is found at point 510, with PA power off shown at 512. Carrier power is measured in a predefined bandwidth, which may be gated from 50-90% of the burst. Next, tune to the offset frequency. Power is then measured at the offset, again in a predefined bandwidth, which may also be gated from 50-90% of the burst. The offset power is then subtracted from the carrier power and relative dB is reported. The process is repeated for all values in the offset list. As described, this process also requires an external analyzer.

A further embodiment provides for self-test of GSM/EDGE transmission and feedback receiver capture. To measure the ORFS modulation at a desired frequency, such as 400 KHz, a Fast Fourier transform (FFT) is plotted with only the receive PLL tuned to the right channel. The noise floor of the receiver is then measured. The transmit chain is then turned on and the difference is measured.

To measure the ORFS switch at a desired frequency, such as 400 KHz, the IQ capture is timed to align with the GSM transmit slot. It may not be possible to capture the entire transmit slot including the power amplifier (PA) ramp up and down, the slot boundary for transmit that includes the PA may be captured. This is done by turning on the PA, examining the PA ramp, and capturing the first 20% of the transmit slot during the rise. This operation is then repeated for the fall.

EVM measurements are derived is a manner similar to phase and frequency error measurements. A test receiver or analyzer samples the transmitter output and captures the actual vector trajectory (both magnitude and phase information). This is then demodulated and the idea vector trajectory is derived. Subtracting one from the other results in an error signal. The required statistical values may then be calculated from this signal. EVM is expressed as a percentage of the nominal signal vector magnitude and RMS peak and 95^{th} percentile values are needed. The 95^{th} percentile is defined as the percent value that 95% of the EVM samples are below, and as a result, is always larger than the RMS value, and smaller than the peak.

Origin offset may also be derived as part of the modulation accuracy measurement. This is a measure of the DC offset in the I and Q paths of the transmitter and is expressed in dB (as a ration of nominal signal vector magnitude). Frequency error may also be derived from this measurement.

Next, multiple instances are captured of the same transient and the maximum is selected to represent the worst ORFS measurement. For EDGE error vector magnitude (EVM) measurement transmit and receive samples from the feedback receiver are captured and the broadband access server (BAS) algorithm for time aligned capture is used for the sample capture. EVM is an important measure of the performance of a radio demodulator and is useful in evaluation modem performance. The EVM is then computed based on error vector simulation of the error vector for each sample.

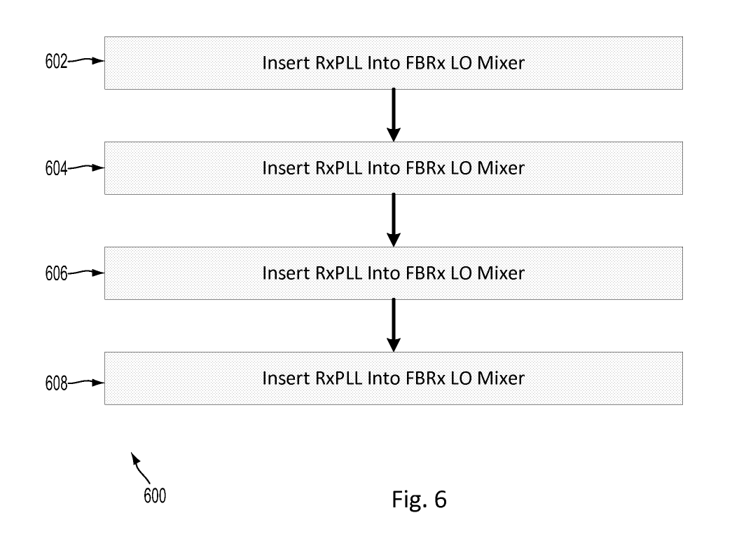

FIG. 6 is a flow diagram of a method for measuring transmit power. The method 600 begins when a new Rx PLL device is inserted into the feedback receive local oscillator mixer in step 602. The receive PLL is then tuned to the transmit local oscillator frequency in step 604. Next, in step 606 the IQ signal is captured using the feedback receive channel. Finally, in step 608, calculate transmit power by summing I2+Q2. Alternatively, transmit power may be measured using the feedback receiver automatic gain control (AGC).

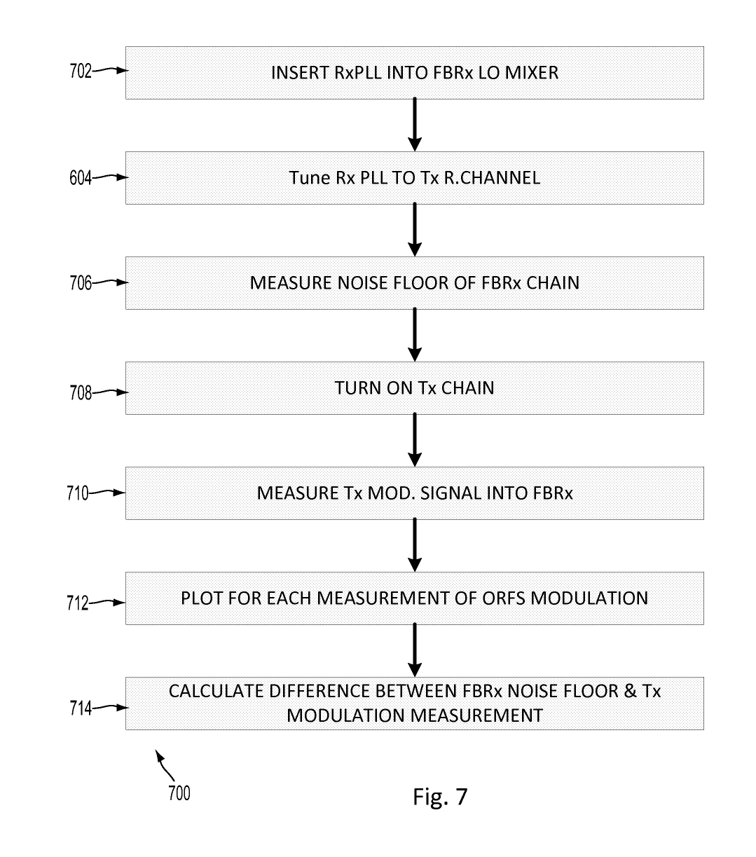

FIG. 7 is a flow diagram of a method for measuring output RF spectrum (ORFS) modulation, according to a further embodiment. The method, 700, begins when a new receive PLL device is inserted into the feedback receive local oscillator mixer in step 702. The transmitter is turned off at this point in the method. The receive PLL is then tuned to the transmit right channel in step 704. In step 706 the noise floor of the feedback receive chain is measured. Once this measurement is made, the transmit chain is turned on in step 708. Next, in step 710, the transmit modulated signal into the feedback receive is measured. A series of measurements are made as described above. In step 712, the Fast Fourier Transform (FFT) is plotted for each measurement made of the ORFS modulation. Once the plots have been made, the difference between the feedback receiver noise floor and the transmit modulation measurement is calculated in step 7114. This calculated difference represents the ORFX modulation.

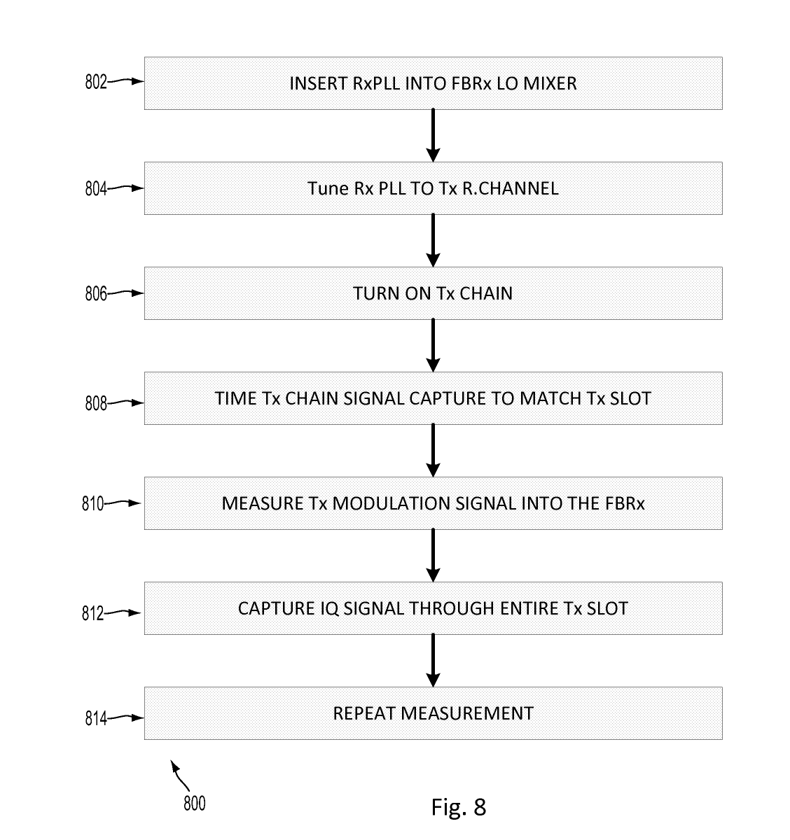

FIG. 8 is a flow diagram of a method of measuring output RF switching, according to a yet further embodiment. The method, 800, begins when a new receive PLL is inserted into the feedback receiver LO in step 802. Next, in step 804, the receive PLL is tuned to the right transmit channel. At this point, in step 806, the transmit chain is turned on. Next, in step 808, the receive chain signal capture is timed to match the transmit slot. The transmit modulation signal into the feedback receiver is then measured in step 810. In step 812 the IQ signal is captured through the entire transmit slot. Step 814 provides for the measurement to be repeated to provide for a desired representative number of measurements.

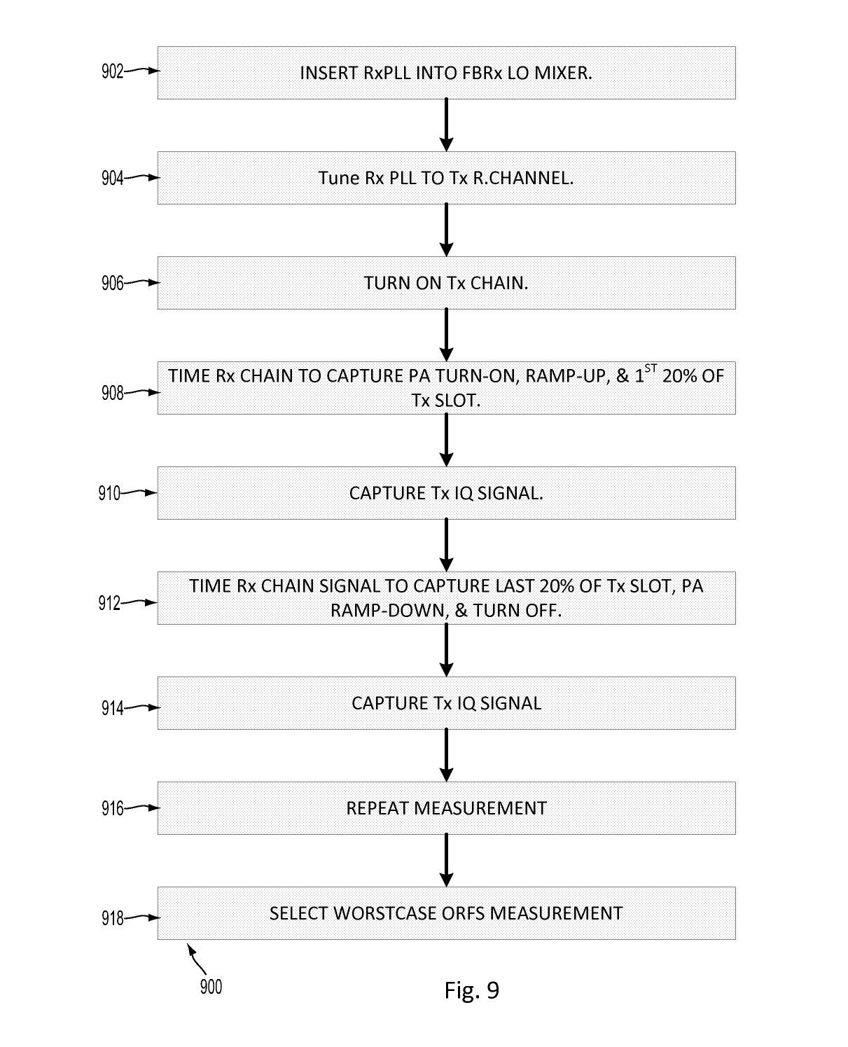

FIG. 9 is a flow diagram of a method of measuring output RF switching by capturing transmit slot boundaries, as a still further embodiment. The method 900 begins in step 902 when a new receive PLL is inserted into the feedback receive LO mixer. At this point in the testing process, the transmitter is off. In step 906 the transmit chain is turned on. Step 908 provides that capture of the receive chain is timed to capture the turning on of the power amplifier. In step 910 the transmit IQ signal is captured. Step 912 provides that the receive chain signal capture is timed to capture the last 20% of the transmit slot, PA ramp-down, and PA turn off. In step 914 the transmit IQ signal is captured. Step 916 provides for the measurements to be repeated so as to collect a representative set of measurements. In step 918 the maximum ORFS measurement is selected as the representative measurement of the worst case

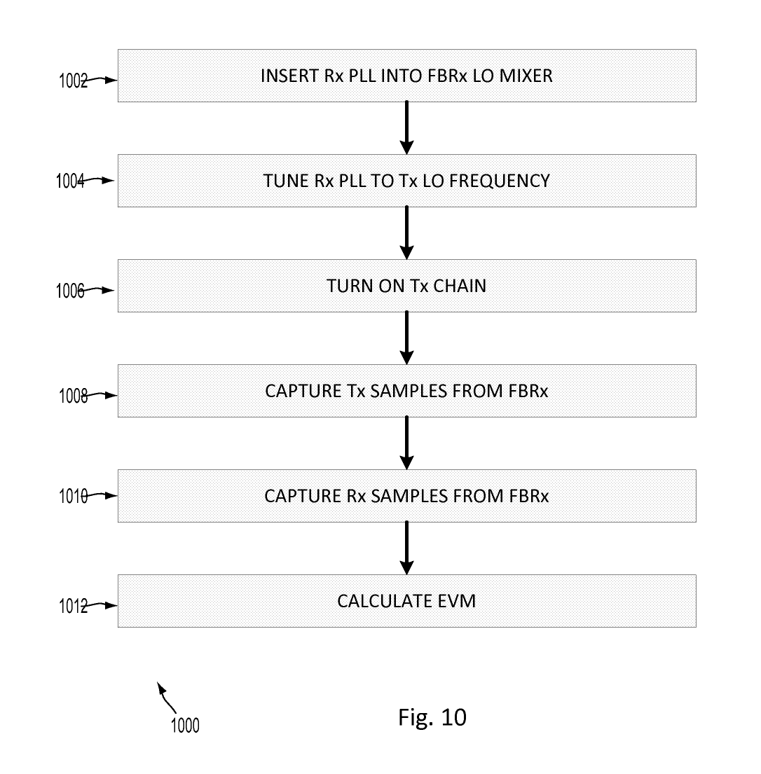

FIG. 10 is a flow diagram of a method of measuring EDGE EVM in accordance with an additional embodiment. The method 1000 begins in step 1002 when a new receive PLL is inserted into the feedback local oscillator mixer. At this point, the transmit chain is off. In step 1004 the receive PLL is tuned to the transmit local oscillator frequency. The transmit chain is turned on in step 1006. Transmit samples are captured from the feedback receiver in step 1008. Receive samples are captured from the feedback receiver in step 1010. In step 1012 the EVM is calculated. The EVM may be calculated using the broadband access server (BAS) algorithm for time aligned sample capture based on the error vector summation of the error vector for each sample.

Those of skill in the art would understand that information and signals may be represented using any of a variety of different technologies and techniques. For example, data, instructions, commands, information, signals, bits, symbols, and chips that may be referenced throughout the above description may be represented by voltages, currents, electromagnetic waves, magnetic fields or particles, optical fields or particles, or any combination thereof.

Those of skill would further appreciate that the various illustrative logical blocks, modules, circuits, and algorithm steps described in connection with the exemplary embodiments disclosed herein may be implemented as electronic hardware, computer software, or combinations of both. To clearly illustrate this interchangeability of hardware and software, various illustrative components blocks, modules, circuits, and steps have been described above generally in terms of their functionality. Whether such functionality is implemented as hardware or software depends upon the particular application and design constraints imposed on the overall system. Skilled artisans may implement the described functionality in varying ways for each particular application, but such implementation decisions should not be interpreted as causing a departure from the scope of the exemplary embodiments of the invention.

The various illustrative logical blocks, modules, and circuits described in connection with the exemplary embodiments disclosed herein may be implemented or performed with a general purpose processor, a Digital Signal Processor (DSP), an Application Specific Integrated Circuit (ASIC), a Field Programmable Gate Array (FPGA) or other programmable logic device, discrete gate or transistor logic, discrete hardware components, or any combination thereof designed to perform the functions described herein. A general purpose processor may be a microprocessor, but in the alternative, the processor may be any conventional processor, controller, microcontroller, or state machine. A processor may also be implemented as a combination of computing devices, e.g., a combination of a DSP and a microprocessor, a plurality of microprocessors, one or more microprocessors in conjunction with a DSP core, or any other such configuration.

In one or more exemplary embodiments, the functions described may be implemented in hardware, software, firmware, or any combination thereof. If implemented in software, the functions may be stored on or transmitter over as one or more instructions or code on a computer-readable medium. Computer-readable media includes both computer storage media and communication media including any medium that facilitates transfer of a computer program from one place to another. A storage media may be any available media that can be accessed by a computer. By way of example, and not limitation, such computer-readable media can comprise RAM, ROM EEPROM, CD-ROM or other optical disk storage or other magnetic storage devices, or any other medium that can be used to carry or store desired program code in the form of instructions or data structures and that can be accessed by a computer. Also, any connection is properly termed a computer-readable medium. For example, if the software is transmitted from a website, server, or other remote source using a coaxial cable, fiber optic cable, twisted pair, digital subscriber line (DSL), or wireless technologies such as infrared, radio, and microwave, then the coaxial cable, fiber optic cable, twisted pair, DSL, or wireless technologies such as infrared, radio, and microwave are included in the definition of medium. Disk and disc, as used herein, includes compact disc (CD), laser disc, optical disc, digital versatile disc (DVD), floppy disk and blu-ray disc where disks usually reproduce data magnetically, while discs reproduce data optically with lasers. Combinations of the above should also be included within the scope of computer-readable media.

The previous description of the disclosed exemplary embodiments is provided to enable any person skilled in the art to make or use the invention. Various modifications to these exemplary embodiments will be readily apparent to those skilled in the art, and the generic principles defined herein may be applied to other embodiments without departing from the spirit or scope of the invention. Thus, the present invention is not intended to be limited to the exemplary embodiments shown herein but is to be accorded the widest scope consistent with the principles and novel features disclosed herein.

What is claimed is:

1. A method of measuring transmit power, comprising:
inserting a receive phase locked loop (PLL) into a feedback receiver local oscillator mixer;
tuning the receive PLL to a local oscillator frequency;
capturing an I and a Q signal using a channel of the feedback receiver; and
determining a sum of a double I signal and a double Q channel.

2. The method of claim 1, wherein the feedback receiver automatic gain control (AGC) is measured and used to determine the transmit power in place of determining the sum of a double I and a double Q signal.

3. A method of measuring output RF spectrum modulation, comprising:
inserting a receive phase locked loop (PLL) into a feedback receiver local oscillator mixer; and
tuning the receive PLL to a right transmit channel.

4. The method of claim 3, further comprising:
measuring a noise floor of a feedback receive chain;
applying power to a transmit chain;
measuring a transmit modulation signal into the feedback receiver;
plotting a transform for each transmit modulation measured; and
determining a difference between the feedback receiver noise floor and the measured transmit modulation.

5. The method of claim 4, where the transform is a Fast Fourier Transform (FFT).

6. The method of claim 3, further comprising measuring output RF spectrum switching in a full transmit slot by:
applying power to a transmit chain;
timing receive chain signal capture to match the full transmit slot;
measuring a transmit modulation signal into the feedback receiver;
capturing an IQ signal through the full transmit slot; and
repeating the measurement a predetermined number of times.

7. The method of claim 3, further comprising:
applying power to a transmit chain;
timing a receive chain signal capture to capture power-on of a power amplifier, power amplifier ramp-up, and a first percentage of a transmit slot;
capturing a first transmit IQ signal;
timing a receive chain signal capture to capture a final percentage of the transmit slot, power amplifier ramp-down, and power amplifier power off;
capturing a second transmit IQ signal; and
determining a maximum captured measurement.

8. The method of claim 7, wherein the first percentage of the transmit slot is 20%.

9. The method of claim 7, wherein the final percentage of the transmit slot is 20%.

10. The method of claim 7, wherein the measurements are repeated at least twice.

11. The method of claim 7, wherein the measurements are repeated more than twice.

12. The method of claim 3, wherein the receive PLL is tuned to the transmit local oscillator frequency.

13. The method of claim 12, further comprising:
powering on the transmit chain;
capturing transmit samples from the feedback receiver;
capturing receive samples from the feedback receiver; and
calculating an error vector magnitude for time aligned sample capture, based on error vector summation of an error vector for each sample.

14. An apparatus for self-testing of a communications device, comprising:
a modem assembly;
a power control assembly, including a first phase locked loop and first and second mixers, the second mixer connected to a feedback low noise amplifier and receiving an input from a feedback receiver phase locked loop;
a power amplifier;
a duplexer;
a coupler; and
a switch.

15. The apparatus of claim 14, wherein the modem assembly includes a reference memory and a feedback memory.
